(19) United States
(12) Patent Application Publication
(10) Pub. No.: US 2009/0032900 A1
(43) Pub. Date: Feb. 5, 2009

(54) METHOD OF PROTECTING SHALLOW TRENCH ISOLATION STRUCTURE AND COMPOSITE STRUCTURE RESULTING FROM THE SAME

(75) Inventors: Yao-Chang Wang, Tainan City (TW); Shih-Chieh Hsu, Tainan County (TW); Chih-Chiang Wu, Taichung County (TW); Huang-Yi Lin, Tainan County (TW); Chi-Hong Pai, Tainan County (TW); Tsung-Wen Chen, Tainan County (TW); Hung-Ling Shih, Tainan County (TW)

Correspondence Address: J C PATENTS, INC., 4 VENTURE, SUITE 250, IRVINE, CA, 92618, US

(73) Assignee: UNITED MICROELECTRONICS CORP., HSINCHU (TW)

(21) Appl. No.: 11/833,789

(22) Filed: Aug. 3, 2007

(51) Int. Cl. H01L 29/00; H01L 21/762

(52) U.S. Cl. 257/510; 438/437; 257/E29.001; 257/E21.546

(57) ABSTRACT

A method of protecting a shallow trench isolation structure is described, which is applied to a semiconductor device process that includes a first process causing a recess in the STI structure and a second process after the first process. The method includes forming a silicon nitride layer in the recess along the profile of the same during the second process.

### BACKGROUND OF THE INVENTION

1. Field of the Invention

This invention relates to a semiconductor process, and more particularly relates to a method of protecting a shallow trench isolation (STI) structure from damages in etching and/or cleaning and to a composite structure resulting from the same method.

2. Description of Related Art

The major isolation structure applied to highly integrated semiconductor devices currently is the shallow trench isolation (STI) structure, which is generally fabricated by forming a trench in a semiconductor substrate and filling the trench with an insulating material. The STI structure is readily scalable and does not suffer from a bird's beak issue present in a local oxidation (LOCOS) process for forming field oxide isolation, thus being a more ideal type of isolation structure for sub-micron MOS processes.

FIG. 1 depicts a top view of a layout of a semiconductor device structure in the prior art, and FIG. 2 depicts a cross-sectional view of the same along the line A-A′. Referring to FIGS. 1 and 2, a STI structure 102 is formed in the substrate 100 to define active areas 103, conductive lines 104 are formed over the substrate 100 crossing over the STI structure 102 and the active areas 103, and spacers 106 are disposed on the sidewalls of the conductive lines 104.

In a MOS process, multiple etching and cleaning steps are conducted, such as the etching step for removing a cap layer and a hard mask layer, the pre-cleaning step done before a salicide layer is formed, the cleaning step conducted after the spacers 106 are formed, and the cleaning step conducted after the source/drain regions are formed, etc.

During the etching and cleaning, the upper portion of each STI structure 102 is damaged to form a recess 108, which possibly has a depth of 800 angstroms or more. Certain wet-etching steps and cleaning steps, especially the pre-cleaning step before the salicide process, cause lateral corrosion to the STI structures 102 so that the recesses 108 extend to below the spacers 106 or even below the conductive lines 104.

In a later deposition step for an inter-layer dielectric (ILD) layer (not shown), seams are formed in the ILD layer due to the presence of the recesses 108. Meanwhile, the deposited material is difficult to fill in the parts of the recesses 108 under the spacers 106 so that there are still hollow spaces under the spacers 106 after the ILD deposition.

It is found that the seams in the ILD layer and the recesses 108 under the spacers 106 lower the isolation effect of the STI structure to cause current leakage. Moreover, in the step of forming tungsten contacts in the ILD layer, tungsten easily fills into the ILD seams and the hollow spaces under the spacers 106 due to its superior gap-filing capability, so that two neighboring tungsten contacts are easily shorted.

### SUMMARY OF THE INVENTION

Accordingly, this invention provides a method of protecting a shallow trench isolation structure, which at least prevents two neighboring contacts from being shorted.

This invention also provides a composite structure resulting from the method of protecting a shallow trench isolation structure of this invention.

A method of protecting a shallow trench isolation structure of this invention is applied to a semiconductor device process that includes a first process causing a recess in the STI structure and a second process after the first process. The method includes formation of a silicon nitride layer in the recess along the profile of the same during the second process.

In an embodiment, the etching rate of the silicon nitride layer is lower than that of the STI structure. The STI structure may include silicon oxide.

In an embodiment, the first process includes an etching process or a cleaning process.

In an embodiment, the second process includes forming a salicide block layer for semiconductor devices isolated by the STI structure, and the salicide block layer and the silicon nitride layer are formed from the same silicon nitride base layer. In another embodiment, the second process includes forming spacers of semiconductor devices isolated by the STI structure, and the spacers and the silicon nitride layer are formed from the same silicon nitride base layer. In still another embodiment, the second process includes forming spacers of semiconductor devices isolated by the STI structure and forming a salicide block layer for semiconductor devices isolated by the STI structure, and the silicon nitride layer includes a first sub-layer and a second sub-layer, wherein the first sub-layer and the salicide block layer are formed from a first silicon nitride base layer, and the second sub-layer and the spacers are formed from a second silicon nitride base layer.

Another method of protecting an STI structure of this invention is applied to a semiconductor device process that includes forming a salicide block layer for semiconductor devices isolated by the STI structure and forming a salicide layer later. In the method, a protection layer is formed over the substrate covering the STI structure after the STI structure is formed but before the salicide block layer is formed, and then the portions of the protection layer not over the STI structure are removed. The etching rate of the protection layer may be lower than that of the STI structure. The protection layer may include silicon nitride, silicon-rich silicon oxide or silicon oxynitride.

The composite structure of this invention includes an STI structure in the substrate and a protection layer and is formed during a semiconductor device process, wherein the STI structure has a recess thereon and the protection layer covers the recess.

The protection layer may have a lower etching rate than the STI structure The STI structure may include silicon oxide. The protection layer may include silicon nitride, silicon-rich silicon oxide or silicon oxynitride.

In an embodiment, the protection layer and a salicide block layer formed for semiconductor devices isolated by the STI structure are formed from the same base layer in the semiconductor device process. In another embodiment, the protection layer and spacers of semiconductor devices isolated by the STI structure are formed from the same base layer in the semiconductor device process. In still another embodiment, the protection layer includes a first sub-layer and a second sub-layer, wherein the first sub-layer and a salicide block layer formed for semiconductor devices isolated by the STI structure are formed from a first base layer, and the second sub-layer and spacers of semiconductor devices isolated by the STI structure are formed from a second base layer.

In an embodiment, the surface of the recess is lower than that of the substrate so that at least a portion of the protection layer is located in a trench in which the STI structure is disposed.

Because a protection layer is disposed on the STI structure having a recess thereon, it is possible to prevent deepening and lateral extension of the recess in subsequent etching and cleaning, so that the isolation effect of the STI structure is maintained. Further, because the protection layer prevents extension of recesses on the isolation layer and thereby inhibits formation of seams in the ILD, two neighboring contacts are prevented from being shorted with this invention.

It is also noted that by integrating the forming steps of the protection layer with those of one or more other functional layers like salicide block layer and/or spacer, the semiconductor device process does not become more complicated.

In order to make the aforementioned and other objects, features and advantages of the present invention comprehensible, a preferred embodiment accompanied with figures is described in detail below.

### BRIEF DESCRIPTION OF THE DRAWINGS

FIG. 1 depicts a top view of the layout of a semiconductor device structure in the prior art.

FIG. 2 depicts a cross-sectional view of the structure of FIG. 1 along line A-A′.

FIG. 3 depicts a top view of the layout of a semiconductor device structure at the start of a process flow for forming a protection layer on the STI structure according to a first embodiment of this invention.

FIGS. 4A-4C depict, in a cross-sectional view along the line B-B′ in FIG. 3, the process flow according to the first embodiment of this invention.

FIG. 5 depicts a top view of a composite structure including an STI structure and a protection layer thereon according to a second embodiment of this invention.

FIG. 6 depicts a cross-sectional view of the composite structure of FIG. 5 along the line C-C′.

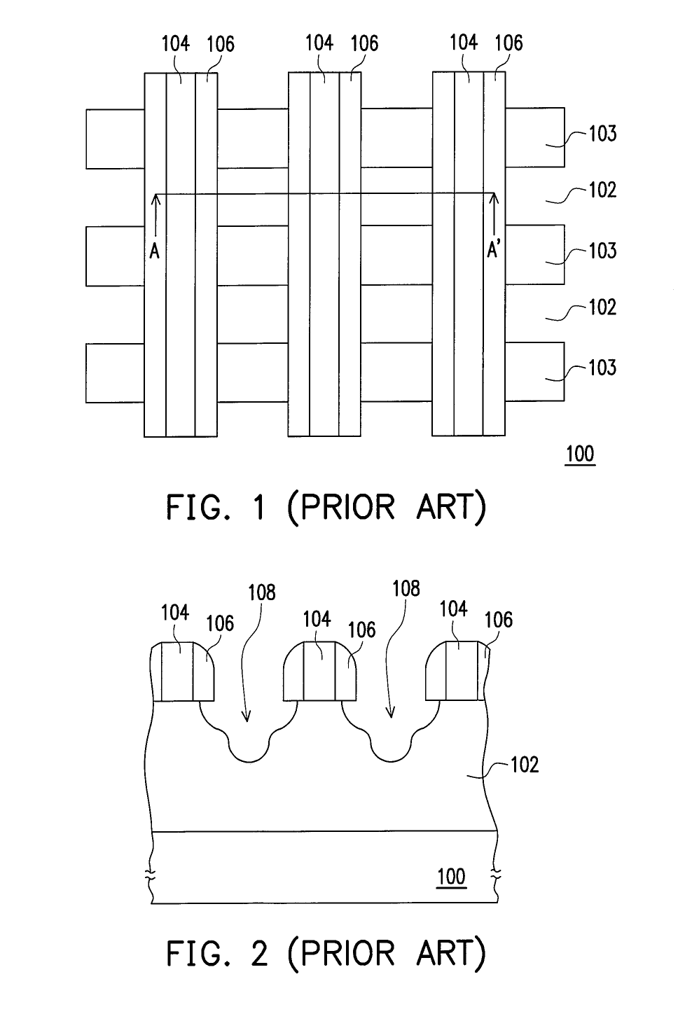

### DESCRIPTION OF EMBODIMENTS

It is particularly noted that the above protection layer on the STI structure may be formed from an additional material layer that was never formed in the corresponding semiconductor device process of the prior-art, or alternatively be formed from one or more material layers used to form other functional layers in a semiconductor device process. In the latter way, the forming steps of the protection layer are integrated with those of one or more other functional layers in the semiconductor device process.

### First Embodiment

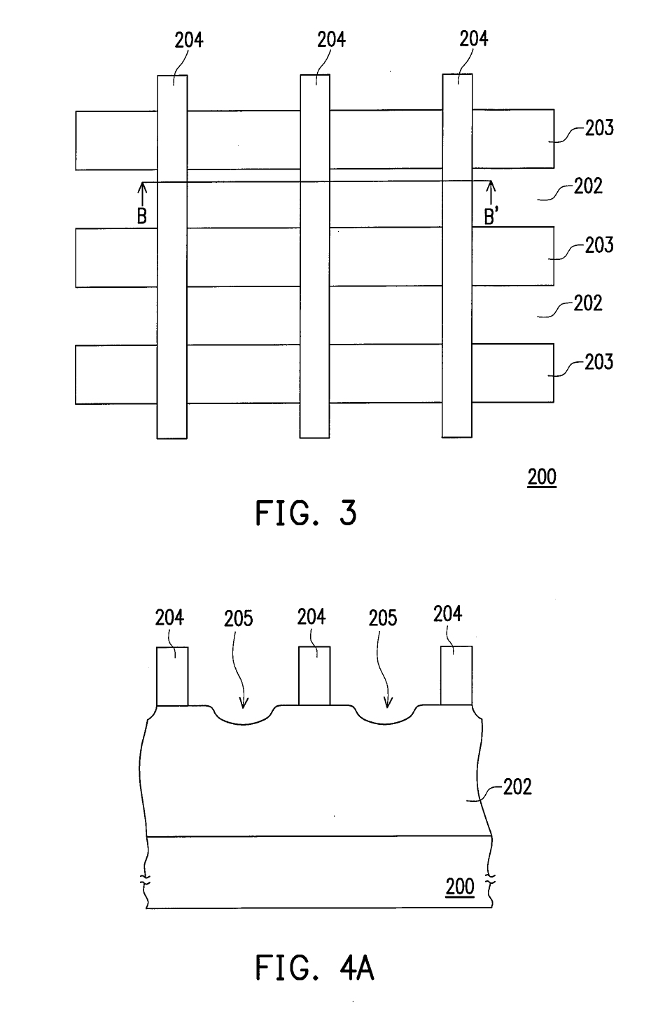

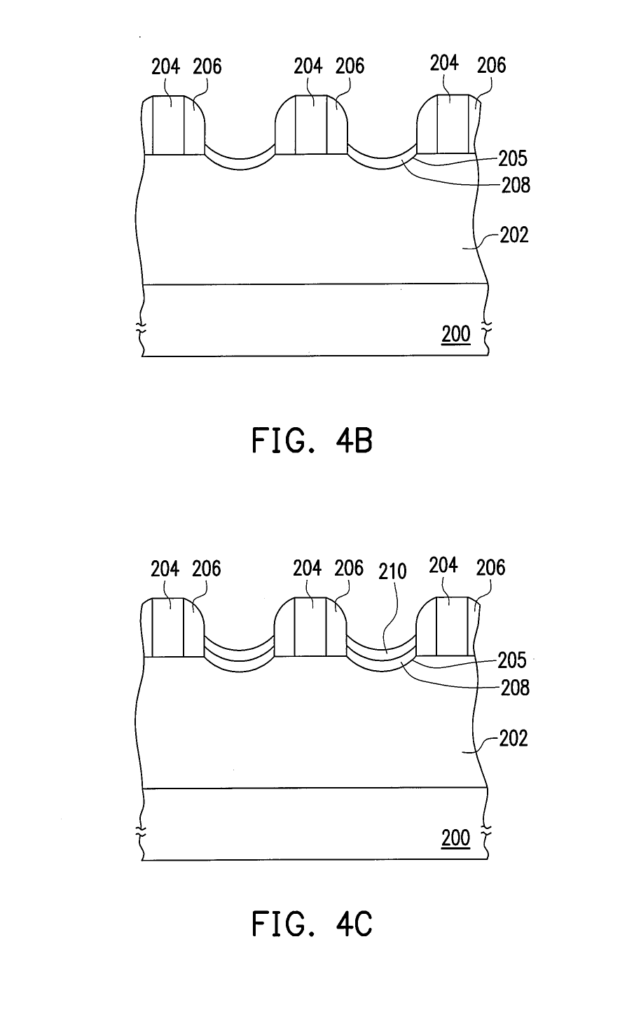

FIG. 3 depicts a top view of the layout of a semiconductor device structure at the start of a process flow for forming a protection layer on the STI structure according to the first embodiment of this invention. FIGS. 4A-4C depict, in a cross-sectional view along the line B-B′ in FIG. 3, the above process flow. In this embodiment, the forming steps of the protection layer are integrated with those of one or more other functional layers in a semiconductor device process.

Referring to FIGS. 3 & 4A, a substrate 200 is provided, with an STI structure 202 formed therein to define active areas 203 and conductive lines 204 formed thereon that cross over the isolation structures 202 and possibly include doped polysilicon. The STI structure 202 may include silicon oxide. The STI structure 202 and the conductive lines 204 can be formed with any suitable process in the prior art.

It is noted that after the STI structure 202 is formed, the etching step for defining the conductive lines 204 and a later cleaning step easily corrode the STI structure 202 to form therein recesses 205 each having a surface lower than that of the substrate 200, which however do not affect the isolation effect of the STI structure 202 or make neighboring contacts formed later be shorted.

Referring to FIG. 4B, spacers 206 of the semiconductor devices isolated by the STI structure 202 are formed on the sidewalls of the conductive lines 204 that are also a part of the semiconductor devices, and simultaneously a protection layer 208 is formed in each recess 205 along the profile of the same. Since the surface of each recess 205 is lower than that of the substrate 200, at least a portion of the protection layer 208 is disposed in the trench in which the STI structure 202 is disposed. The spacers 206 and the protection layer 208 are formed from the same base layer, and the protection layer 208 has a lower etching rate than the STI structure 202. To form the spacers 206 and the protection layer 208, it is possible to deposit a silicon nitride base layer over the substrate 200 through CVD and then etch back the same such that the portions thereof on the sidewalls of the conductive lines 204 and on the STI structure 202 are retained.

Referring to FIG. 4C, a protection layer 210 is formed on the STI structure 202, and simultaneously a salicide block layer (not shown) is formed over the substrate 200 for some semiconductor devices isolated by the STI structure 202. The salicide block layer and the protection layer 210 are formed from the same base layer, and the protection layer 210 has a lower etching rate than the STI structure 202. To form the salicide block layer and the protection layer 210, it is possible to deposit a silicon nitride base layer over the substrate 200 through CVD and then pattern the same such that the regions of the substrate 200 on which a salicide layer is to be formed are exposed, while the portions of the silicon nitride base layer on the STI structure 202 and on the regions of the substrate 200 not requiring salicide are retained.

It is particularly noted that when the two protection layers 208 and 210 together are considered as one protection layer, each of the two protection layers 208 and 210 is considered as a sub-layer of the one protection layer.

It is noted that though two protection layers 208 and 210 are successively formed over the STI structure 202 in the first embodiment, this invention is not limited to form two protection sub-layers but may alternatively form only one protection layer simultaneously with a functional layer like a salicide block layer or a spacer.

It is also noted that when only one protection layer is formed simultaneously with a salicide block layer in a later stage of a MOS process, the accumulative corrosion to the STI structure during previous steps makes a deeper recess thereon. In such a case, however, the protection layer still effectively ensures the isolation effect of the STI structure as being formed still before the pre-cleaning step prior to the salicide process which would damage an unprotected STI structure badly.

Accordingly, since a protection layer (possibly including two sub-layers 208 and 210) is formed on the STI structure 202, it is possible to prevent deepening or lateral extension of the recesses on the same in subsequent etching and cleaning. Hence, the isolation effect of the STI structure can be maintained and neighboring contacts can be prevented from being shorted.

In addition, because the forming steps of the protection layers 208 and 210 are integrated with the inherent steps of a MOS process, the MOS process does not become more complicated.

### Second Embodiment

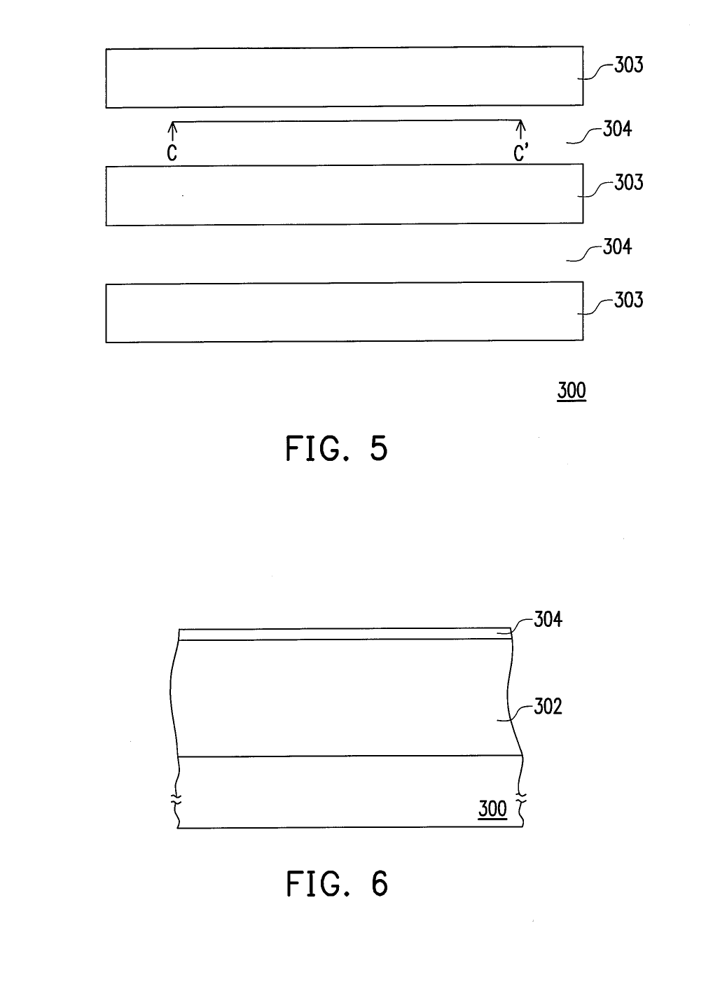

FIG. 5 depicts a top view of a composite structure including an STI structure and a protection layer thereon according to the second embodiment of this invention. FIG. 6 depicts a cross-sectional view of the composite structure of FIG. 5 along line C-C′. In this embodiment, the protection layer is formed from an additional material layer never formed in the corresponding semiconductor device process of the prior art.

Referring to FIGS. 5-6, a substrate 300 is provided with an STI structure 302 formed therein that defines active areas 303. The STI structure 302 may include silicon oxide, and may be formed with any suitable process in the prior art.

A protection layer 304 is formed on the flat surfaces of the STI structure 302, including a material having a lower etching rate than that of the STI structure 302, such as silicon nitride (SiN), silicon-rich silicon oxide or silicon oxynitride (SiON). To from the protection layer 304, it is possible to form a base layer (not shown) as a precursor thereof over the entire substrate 300 and then pattern the same to remove the portions thereof not over the STI structure 302.

It is particularly noted that the protection layer 304 is formed immediately after the STI structure 302 is formed, so that the STI structure 302 is not damaged by subsequent etching or cleaning and can have a substantially flat surface.

In other embodiments, the protection layer formed from an additional material layer may not be formed immediately after the STI structure is formed, because the protection layer can ensure the desired functions of the STI structure if only it is formed before the pre-cleaning step prior to the salicide process which would damage an unprotected STI structure badly.

Because a protection layer is formed/disposed on the STI structure having a recess therein, it is possible to prevent deepening and extension of the recess in later etching and cleaning, so that the isolation effect of the STI structure is maintained. Further, because the protection layer prevents extension of the recesses in the STI layer, two neighboring contacts are prevented from being shorted. In addition, by integrating the forming steps of the protection layer with those of one or more other functional layers like a salicide block layer and/or a spacer, the semiconductor device process does not become more complicated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of protecting a shallow trench isolation (STI) structure, applied to a semiconductor device process that includes a first process causing a recess in the STI structure and a second process after the first process, and comprising:
forming a silicon nitride layer in the recess along a profile of the recess during the second process.

2. The method of claim 1, wherein an etching rate of the silicon nitride layer is lower than an etching rate of the STI structure.

3. The method of claim 1, wherein the STI structure comprises silicon oxide.

4. The method of claim 1, wherein the first process comprises an etching process or a cleaning process.

5. The method of claim 1, wherein the second process comprises forming a salicide block layer for semiconductor devices isolated by the STI structure, and the salicide block layer and the silicon nitride layer are formed from the same silicon nitride base layer.

6. The method of claim 1, wherein the second process comprises forming spacers of semiconductor devices isolated by the STI structure, and the spacers and the silicon nitride layer are formed from the same silicon nitride base layer.

7. The method of claim 1, wherein the second process includes forming spacers of semiconductor devices isolated by the STI structure and forming a salicide block layer for semiconductor devices isolated by the STI structure, and the silicon nitride layer includes a first sub-layer and a second sub-layer, wherein the first sub-layer and the salicide block layer are formed from a first silicon nitride base layer and the second sub-layer and the spacers are formed from a second silicon nitride base layer.

8. A method of protecting a shallow trench isolation (STI) structure, applied to a semiconductor device process that includes forming a salicide block layer for semiconductor devices isolated by the STI structure and forming a salicide layer subsequently, and comprising:
forming over the substrate a protection layer covering the STI structure after the STI structure is formed but before the salicide block layer is formed, and removing portions of the protection layer that are not over the STI structure.

9. The method of claim 8, wherein an etching rate of the protection layer is lower than an etching rate of the STI structure.

10. The method of claim 8, wherein the protection layer comprises silicon nitride, silicon-rich silicon oxide or silicon oxynitride.

11. A composite structure comprising a shallow trench isolation (STI) structure in a substrate and a protection layer and being formed during a semiconductor device process, wherein the STI structure has a recess thereon, and the protection layer covers the recess.

12. The composite structure of claim 11, wherein the protection layer has a lower etching rate than the STI structure.

13. The composite structure of claim 11, wherein the STI structure comprises silicon oxide.

14. The composite structure of claim 11, wherein the protection layer comprises silicon nitride, silicon-rich silicon oxide or silicon oxynitride.

15. The composite structure of claim 11, wherein the protection layer and a salicide block layer formed for semiconductor devices isolated by the STI structure are formed from the same base layer in the semiconductor device process.

16. The composite structure of claim 11, wherein the protection layer and spacers of semiconductor devices isolated by the STI structure are formed from the same base layer in the semiconductor device process.

17. The composite structure of claim 11, wherein the protection layer includes a first sub-layer and a second sub-layer, wherein the first sub-layer and a salicide block layer formed for semiconductor devices isolated by the STI structure are formed from a first base layer, and the second sub-layer and spacers of semiconductor devices isolated by the STI structure are formed from a second base layer.

18. The composite structure of claim 11, wherein a surface of the recess is lower than a surface of the substrate so that at least a portion of the protection layer is located in a trench in which the STI structure is disposed.
